(19) United States
(12) Patent Application Publication
(10) Pub. No.: US 2026/0098915 A1
(43) Pub. Date: Apr. 9, 2026

(54) BRIDGE DETECTION TEST PATTERN AND RELATED METHODS

(71) Applicant: Taiwan Semiconductor Manufacturing Company Limited, Hsin-Chu (TW)

(72) Inventor: Tung-Ying WU, Hsinchu City (TW)

(21) Appl. No.: 18/906,378

(22) Filed: Oct. 4, 2024

(51) Int. Cl. G01R 31/52; G01R 31/54

(52) U.S. Cl. CPC G01R 31/52; G01R 31/54

(57) ABSTRACT

A device is provided. The device comprises: an active circuit region including a first active conductive feature; and a test pattern offset from the active conductive feature. The test pattern includes: a first conductive feature in a first metal layer; a second conductive feature in the first metal layer; a first test voltage supply line in a second metal layer below the first metal layer and electrically connected to the first conductive feature; and a second test voltage supply line in a third metal layer below the second metal layer and electrically connected to the second conductive feature.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a diagrammatic plan view of a semiconductor wafer including integrated circuit (IC) dies, in accordance with some embodiments.

FIG. 1B illustrates a detailed plan view of a region of the semiconductor wafer of FIG. 1A including test patterns, in accordance with some embodiments.

FIG. 2A illustrates a diagrammatic plan view of a test pattern, in accordance with some embodiments.

FIG. 2B illustrates a diagrammatic side view of the test pattern of FIG. 2A along cross-sectional line B-B, in accordance with some embodiments.

FIG. 2C illustrates a diagrammatic side view of the test pattern of FIG. 2A along cross-sectional line B-B, in accordance with some embodiments.

FIG. 2D illustrates a diagrammatic side view of the test pattern of FIG. 2A along cross-sectional line D-D, in accordance with some embodiments.

FIG. 2E illustrates a diagrammatic plan view of a test pattern, in accordance with some embodiments.

FIG. 2F illustrates a diagrammatic side view of the test pattern of FIG. 2E along cross-sectional line F-F, in accordance with some embodiments.

FIG. 2G illustrates a diagrammatic side view of the test pattern of FIG. 2E, in accordance with some embodiments.

FIG. 2H illustrates a diagrammatic side view of a test pattern including a well bridge defect, in accordance with some embodiments.

FIG. 2I illustrates a diagrammatic side view of the test pattern including a via bridge defect, in accordance with some embodiments.

FIG. 3A illustrates a schematic view of an electronic test circuit for detecting a bridge defect, in accordance with some embodiments.

FIG. 3B illustrates a schematic view of the electronic test circuit of FIG. 3A in a first detecting state, in accordance with some embodiments.

FIG. 3C illustrates a schematic view of an electronic test circuit for detecting a bridge defect, in accordance with some embodiments.

FIG. 3D illustrates a schematic view of an electronic test circuit that is electronically connected to a test pattern, in accordance with some embodiments.

FIG. 3E illustrates a schematic view of at least two electronic test circuits that are electronically connected to a test pattern, in accordance with some embodiments.

FIG. 4A illustrates a diagrammatic plan view of a test pattern, in accordance with some embodiments.

FIG. 4B illustrates a diagrammatic plan view of a test pattern, in accordance with some embodiments.

FIG. 5 illustrates a schematic view of a portion of an IC die including a test pattern, in accordance with some embodiments.

FIG. 6 is a flow diagram illustrating a method of using a test pattern, in accordance with some embodiments.

FIG. 7 is a flow diagram illustrating a method of using a test pattern, in accordance with some embodiments.

FIG. 8 is a flow diagram illustrating a method of using a test pattern, in accordance with some embodiments.

FIG. 9 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, separation distance or spacing between adjacent features, such as conductive pads or vias of an interconnect structure, is reduced. This reduction in spacing can result in an increased occurrence of electrical bridging between the adjacent features. For example, a bridging defect can occur when excess material forms a connection between two tiny conductive pathways (e.g., vias) in a semiconductor circuit. With progress in advanced semiconductor process nodes, separation distance or spacing between adjacent features, such as conductive pads or vias of an interconnect structure, is reduced. This reduction in spacing can result in an increased occurrence of electrical bridging between the adjacent features.

A bridging defect can occur when excess material forms a connection between two tiny conductive pathways (e.g., vias) in a semiconductor circuit. During processes like chemical vapor deposition (CVD), excess material can build up that bridges the gap between vias. This can be caused by uneven deposition rates, temperature fluctuations, or contamination in the chamber. Imperfect etching can leave residual material behind, creating a bridge. This can happen due to non-uniform etching across the wafer, over-etching that removes too much material, or under-etching that leaves unwanted residues. Tiny particles like dust or metallic flakes can land between vias and form a conductive bridge. This can occur during any stage of processing if proper cleaning and filtration are not implemented. Photoresist, a light-sensitive material used for patterning, can malfunction. If it does not properly define the via openings, improper material deposition or incomplete etching can lead to bridging. A single bottom conductive line can be included in a test pattern that electrically couples to all conductive pads of the test pattern. Resistance variations in the bottom conductive line can be detected to determine whether a bridging defect is present in the conductive pads. However, while the single bottom conductive line can be used to determine that the bridging defect is present among the conductive pads coupled thereto, precise position of the bridging defect is difficult to determine. For example, in a four-by-four array of conductive pads including sixteen conductive pads, presence of a bridging defect can be determined based on resistance of the bottom conductive line, however, which two of the conductive pads are affected by the bridging defect is difficult to determine. As such, additional optical inspection or another suitable inspection may be performed to isolate the position of the bridging defect and conductive pads affected thereby.

In embodiments of the disclosure, at least two bottom conductive lines that are staggered relative to each other are positioned under and electrically coupled to the conductive pads. Each of the bottom conductive lines can be electrically connected to a single conductive pad of the conductive pads. A voltage difference can be applied across two of the bottom conductive lines to determine whether a bridging defect is present between the two bottom conductive lines based on leakage current generated through the bridging defect. The test pattern can be positioned in an active circuit region of an IC chip or die, in a keep-out region of the IC chip or die or in a scribe line between neighboring IC chips or dies. Conductive features of the test pattern can have size that is the same as that of conductive features of the IC chip, exceeds size of the conductive features of the IC chip or is smaller than that of the conductive features of the IC chip. As such, test resolution can be improved and number of different test profiles and/or test types can be increased. This results in improved reliability of the IC chips.

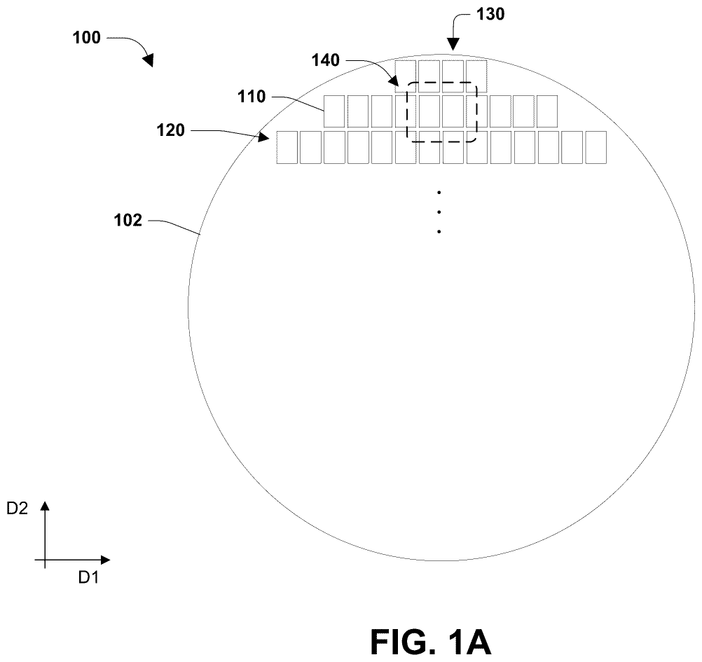

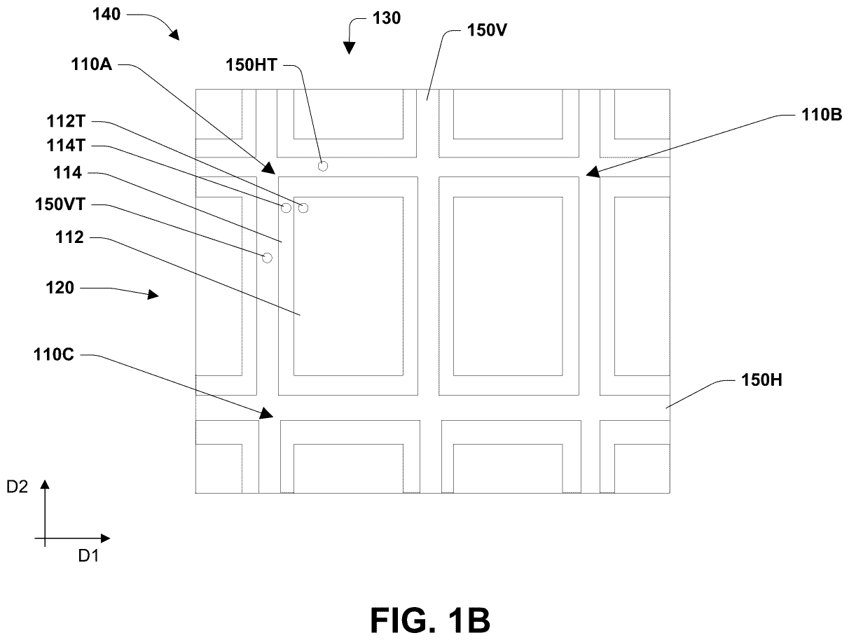

FIG. 1 illustrates an in-process integrated circuit (IC) wafer 100, according to some embodiments.

The in-process IC wafer 100 can include at least two integrated circuit die regions 110 positioned on and/or in a semiconductor substrate 102. The in-process IC wafer 100 can be referred to as an IC wafer 100, a circuit IC wafer 100 or an IC die wafer 100 throughout.

In some embodiments, the semiconductor substrate 102 comprises at least one of a substrate, a photomask, a semiconductor device, a dielectric layer, an epitaxial layer, a silicon-on-insulator (SOI) structure, a semiconductor layer, a conductive material layer, a die, etc. The semiconductor substrate 102 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor substrate 102 comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor substrate 102 are within the scope of the present disclosure.

In some embodiments, the IC die regions 110 can be in-process dies or completed dies that are to be singulated in a subsequent process operation. The IC die regions 110 can be or include microcontrollers (MCUs), microprocessors (MPUs), graphics processing units (GPUs), artificial intelligence (AI) accelerators, memory ICs, analog ICs, logic ICs, optoelectronics, power management ICs, wireless communication ICs. In some embodiments, the IC die regions 110 are arranged in one or more rows 120 and one or more columns 130. The rows 120 extend along a first direction D1 and are arranged along a second direction D2. The columns 130 extend along the second direction D2 and are arranged along the first direction D1. A region 140 is depicted in FIG. 1A by a dashed line and is described in greater detail with reference to FIG. 1B.

In some embodiments, each of the IC die regions 110 includes one or more patterned layers of different materials that are arranged to form electronic circuits. Components of each IC die region 110 of the IC die regions 110 can include transistors, interconnects, capacitors, resistors, inductors and the like. The IC die region 110 can include many material layers, such as the semiconductor substrate 102, epitaxial layers, isolation layers, gate dielectric layers, gate electrode layers, source/drain layers, contact layers, interconnect layers, dielectric layers, passivation layers and the like. Formation of the material layers can include performing one or more semiconductor processes, such as deposition, photolithography, etching, doping, planarization and the like. Along a vertical axis that is perpendicular to the major surface of the IC die region 110, from bottom to top, the IC die region 110 can include a device region and an interconnect region on the device region. The device region can generally include the transistors and capacitors, and the interconnect region can generally include the interconnects as well as capacitors, inductors, resistors and the like. The transistors can be or include field effect transistors (FETs), which can include planar transistors, fin FETs (or “FinFETs”), nanostructure FETs (e.g., nanosheet FETs or the like), vertical FETs, and the like. In some embodiments, the interconnect region can include memory devices, such as phase-change random access memory (PCRAM) devices, magnetoresistive random access memory (MRAM) devices, and/or other suitable memory devices.

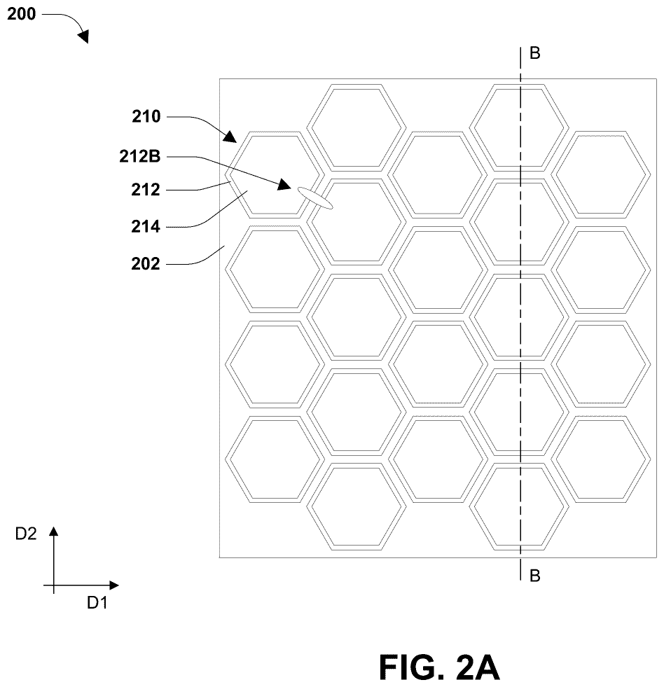

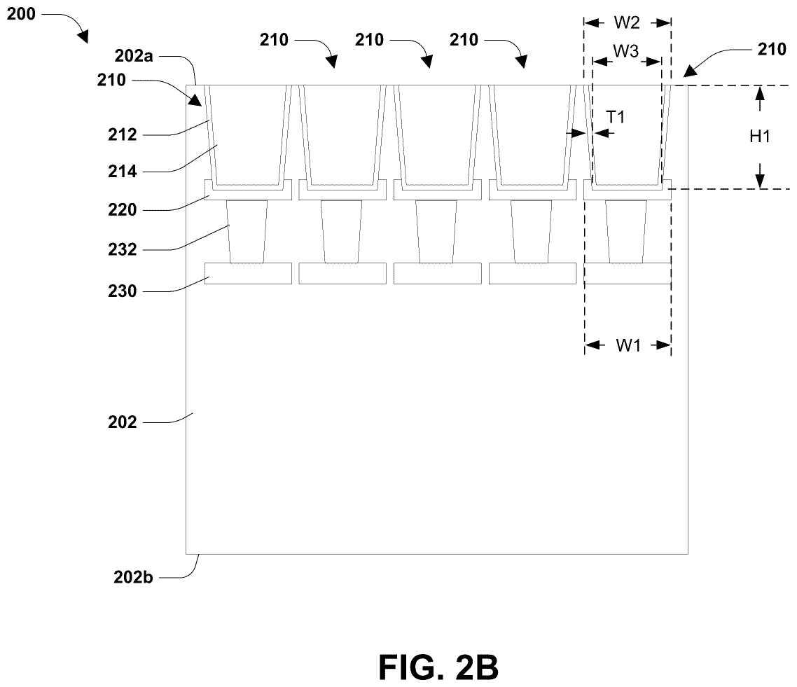

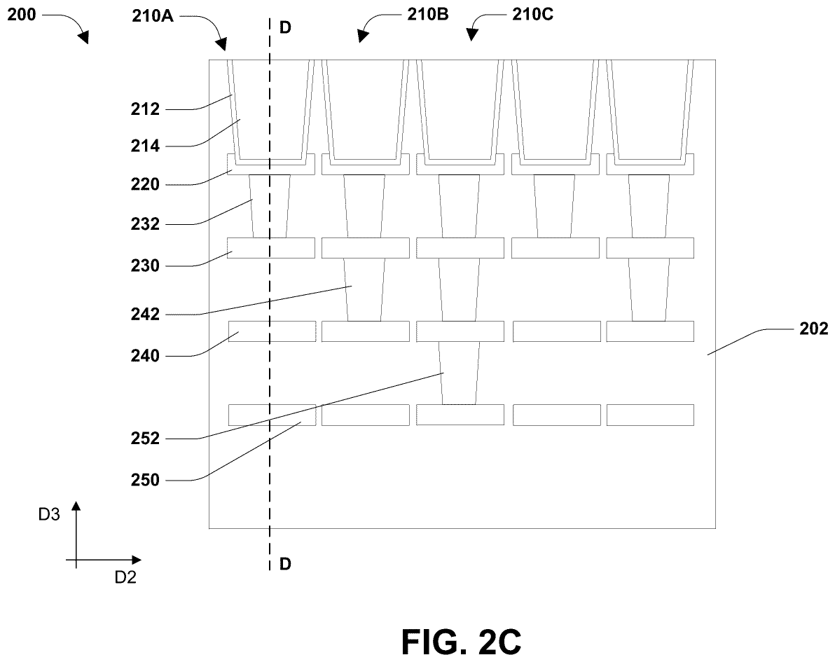

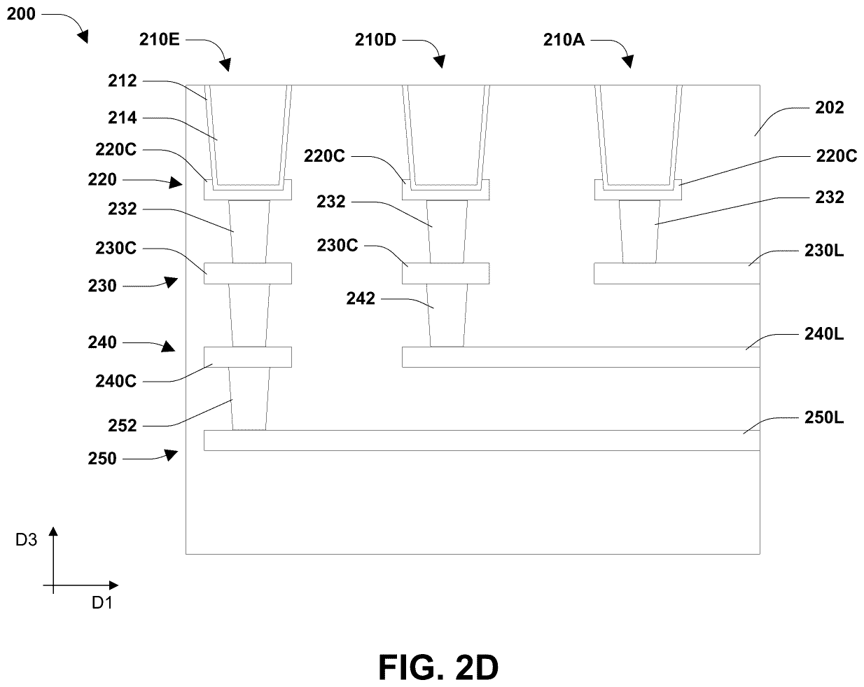

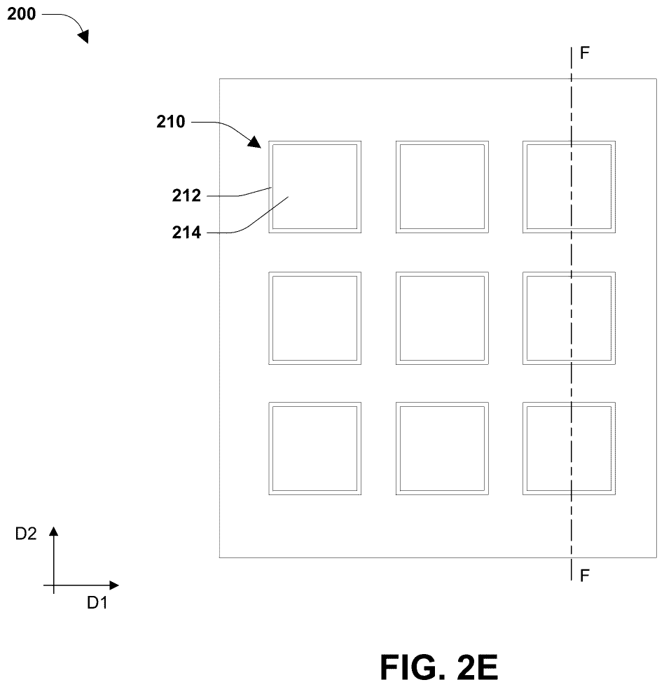

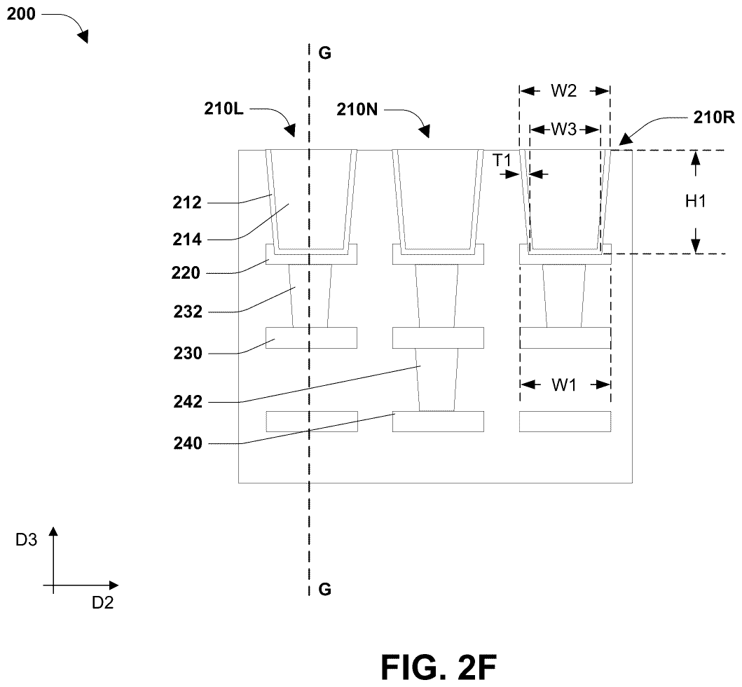

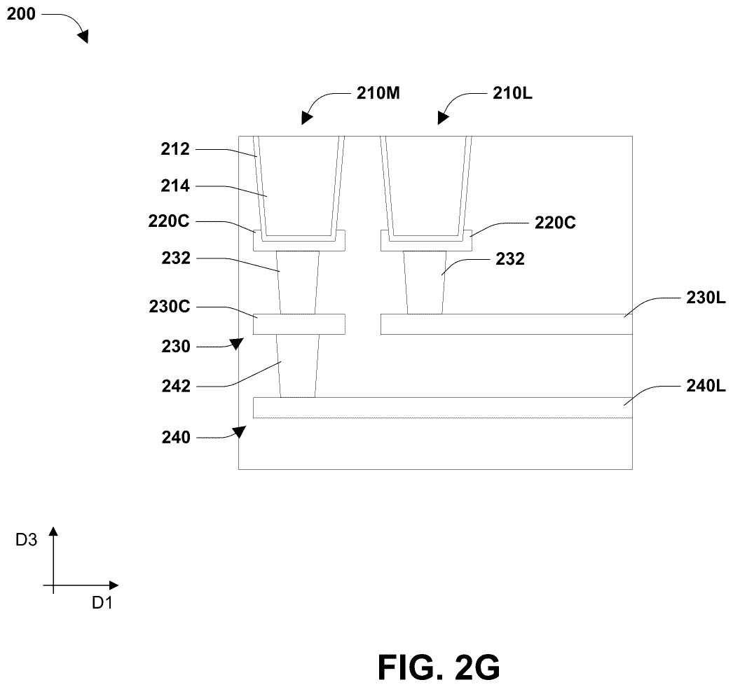

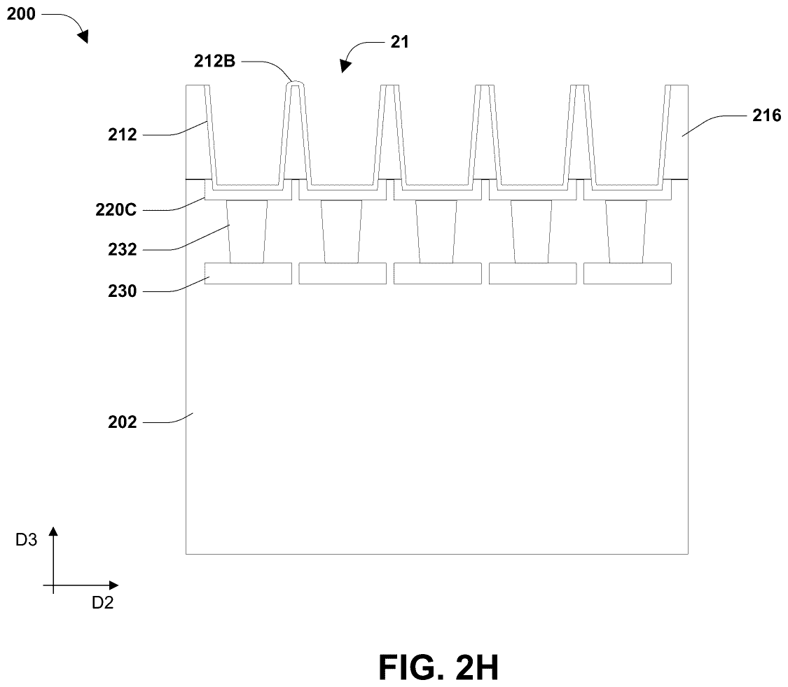

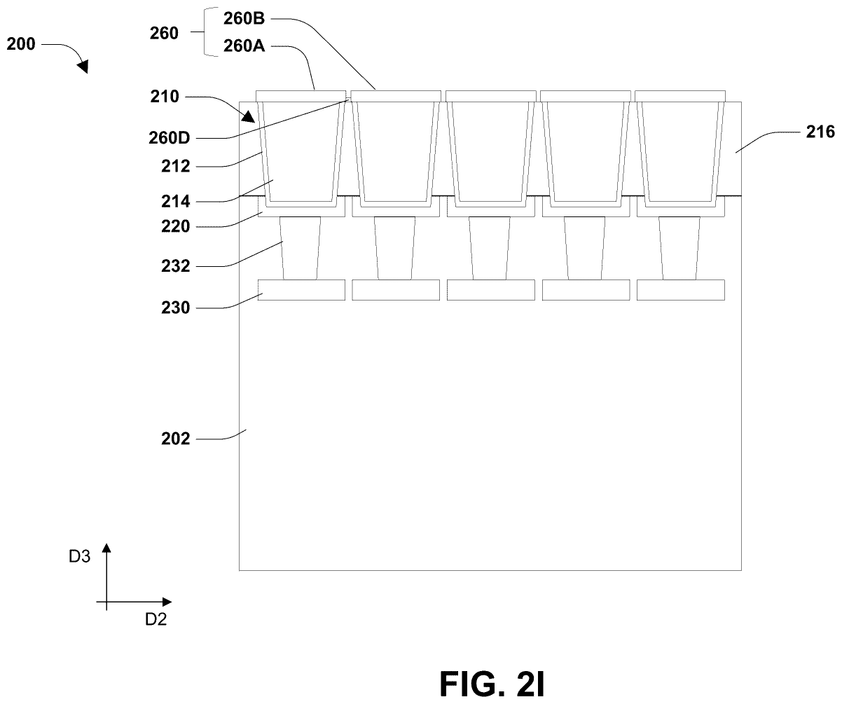

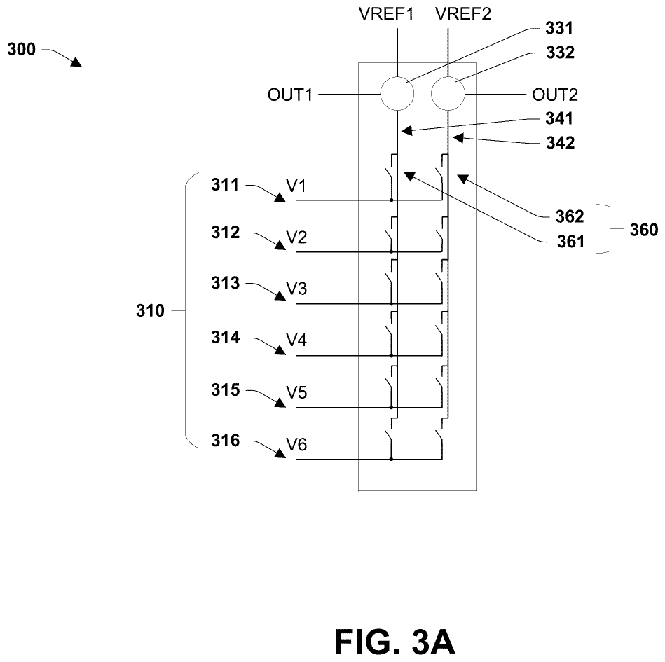

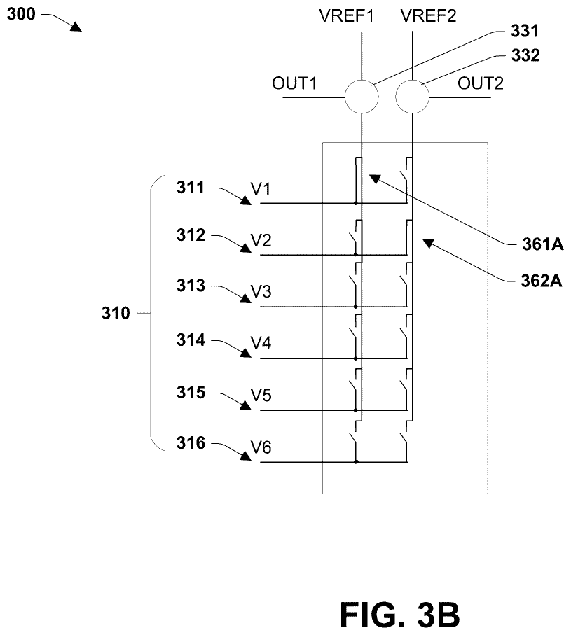

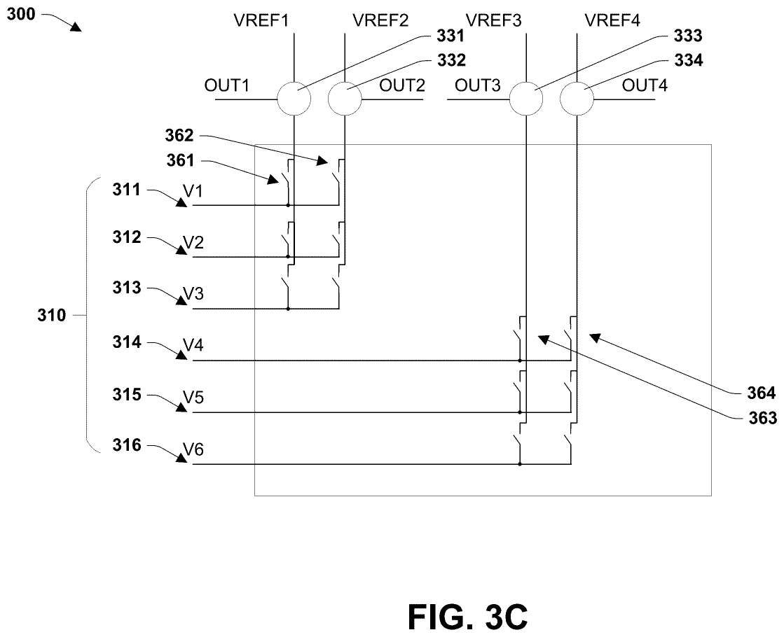

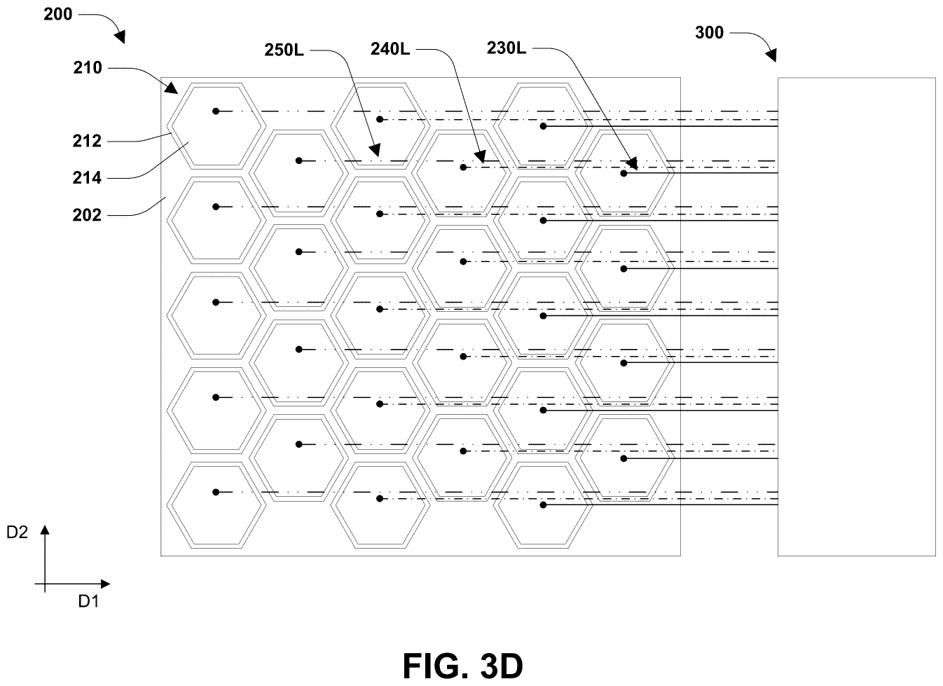

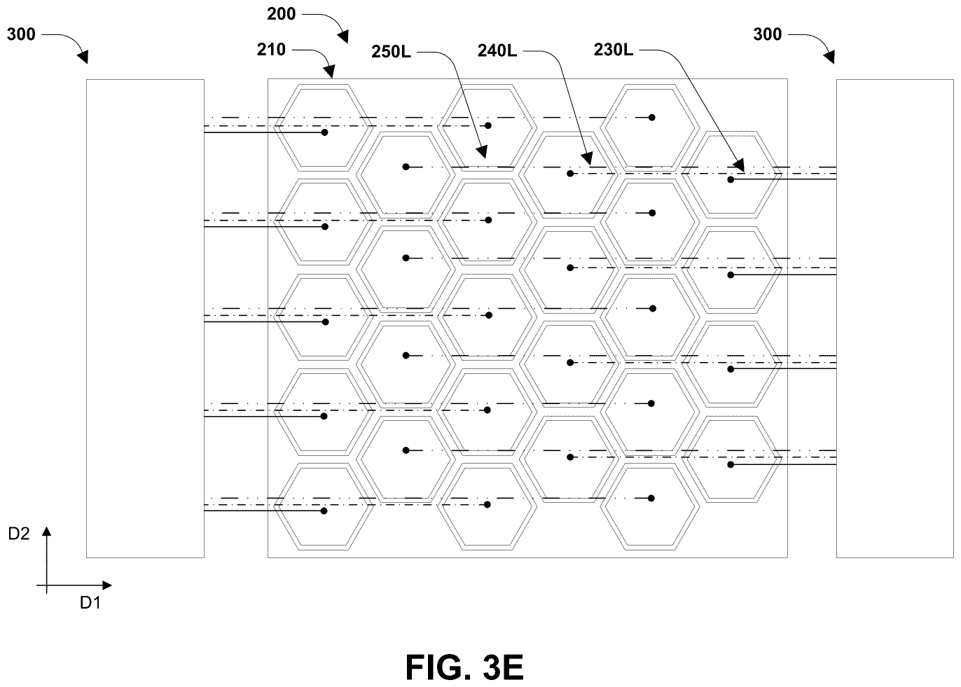

FIG. 1B illustrates a detailed plan view of the region 140 of the IC wafer 100 of FIG. 1A including test patterns 112T, 114T, 150HT, 150VT, in accordance with some embodiments. Embodiments of test patterns 200 that can be the test patterns 112T, 114T, 150HT, 150VT are described in detail with reference to FIGS. 2A-2I. The test patterns 200 can be operated via a test circuit described with reference to FIGS. 3A-3C. Operation of the test patterns 200 can provide beneficial information about process steps in a semiconductor manufacturing process. For example, conductive features 210 of the test patterns 200 can be separated by varied distances to determine design rules for layout of active conductive features of the IC die regions 110. As an example, a design rule for minimum spacing between adjacent conductive features may specify a first dimension. The conductive features 210 of the test pattern 200 may have spacing therebetween that is selected to exceed the minimum spacing or be less than the minimum spacing of the design rule. Detection of a bridging defect in the test pattern 200 can provide information about whether, for example, spacing tighter than that specified by the design rule can be employed safely throughout the IC die regions 110.

In FIG. 1B, a first IC die region 110A, a second IC die region 110B and a third IC die region 110C are positioned in the region 140. The first, second and third IC die regions 110A, 110B, 110C can be referred to collectively as the IC die regions 110A, 110B, 110C or the die regions 110A, 110B, 110C. The first IC die region 110A is immediately adjacent the second IC die region 110B along the first direction D1 with a vertical scribe line 150V positioned therebetween. The first IC die region 110A is immediately adjacent the third IC die region 110C along the second direction D2 with a horizontal scribe line 150H therebetween. Each pair of immediately adjacent columns 130 may have a vertical scribe line 150V positioned therebetween. Each pair of immediately adjacent rows 120 may have a horizontal scribe line 150H positioned therebetween. The horizontal and vertical scribe lines 150H, 150V can be referred to collectively as the scribe lines 150H, 150V. The scribe lines 150H, 150V can be narrow spaces between adjacent dies 110A, 110B, 110C on the IC die wafer 100. Each of the scribe lines 150H, 150V may be free of functional circuit elements but may include test structures used during manufacturing. The scribe lines 150H, 150V provide paths for the IC die wafer 100 to be cut (or scribed) into individual dies, which can be referred to as singulation.

Each of the IC die regions 110A, 110B, 110C includes an active circuit region 112 and a chip perimeter 114. The chip perimeter 114 is positioned between the active circuit region 112 and the scribe lines 150H, 150V. In some embodiments, the chip perimeter 114 laterally surrounds on the active circuit region 112 on at least four sides, such as a front side, a back side, a left side and a right side. In some embodiments, the chip perimeter 114 includes one or more guard rings, seal rings, bond pads, and other structures that protect the active circuit area. The guard rings can protect the active circuit region 112 from electrical noise and interference. The seal rings can provide a physical barrier to prevent contaminants from reaching the active circuit region 112. The bond pads can provide electrical connections between the dies 110A, 110B, 110C and the external package.

The test patterns 112T, 114T, 150HT, 150VT can include first structures that are the same as, substantially the same as or similar to second structures of the IC die regions 110A, 110B, 110C. Difference in dimension(s) of the first structures can be different than dimension(s) of the second structures can be less than about 5%, in some embodiments. The dimension(s) can include width, length, height, combinations thereof and the like. The test pattern 112T is positioned in the active circuit region 112. The test pattern 114T is positioned in the chip perimeter 114. The test pattern 150HT is positioned in the horizontal scribe line 150H. The test pattern 150VT is positioned in the vertical scribe line 150V. In some embodiments, the IC wafer 100 can include one or more of the test pattern 112T, the test pattern 114T, the test pattern 150HT and the test pattern 150VT.

FIG. 2A illustrates a diagrammatic plan view of a test pattern 200, in accordance with some embodiments. FIG. 2B illustrates a diagrammatic side view of the test pattern of FIG. 2A along cross-sectional line B-B, in accordance with some embodiments. The test pattern 200 can be an embodiment of any of the test patterns 112T, 114T, 150HT, 150VT described with reference to FIG. 1B.

In FIG. 2A, the test pattern 200 includes conductive features 210 that have hexagonal profile in the plan view. The conductive features 210 are formed on and/or in a substrate 202, which is similar in most respects to the semiconductor substrate 102 described with reference to FIG. 1A. The substrate 202 can have a top surface 202a and a bottom surface 202b. As depicted in FIG. 2A, the conductive features 210 can be arranged in a honeycomb pattern. The test pattern 200 can be used to determine whether a bridging defect 212B (or “well bridging defect 212B”) is present between an immediately adjacent pair of the conductive features 210. Each of the conductive features 210 can include a liner or barrier layer 212 and a core layer 214 that is on the liner layer 212.

As depicted in FIG. 2B, the liner layer 212 can have thickness T1 that exceeds about 0.5 nanometers (nm), such as being in a range of about 0.5 nm to about 20 nm or another suitable thickness. The liner layer 212 may have width that decreases, such that the conductive feature 210 has a tapered profile. For example, a second width W2 and a third width W3 are depicted in FIG. 2B. The second width W2 can be width of an upper region of the liner layer 212 and the third width W3 can be width of a bottom surface of the liner layer 212. The second width W2 can exceed the third width W3. The second width W2 can be considered an upper width of the conductive feature 210 proximal or coplanar with the top surface 202a of the substrate 202. The third width W3 can be considered a lower width of the conductive feature 210 between the top and bottom surfaces 202a, 202b, for example, at an interface of the liner layer 212 and an underlying first conductive layer 220. In some embodiments, the second width W2 is in a range of about 5 nm to about 100 nm. In some embodiments, the third width W3 is in a range of about 4.5 nm to about 99.5 nm. Other ranges for the second and third widths W2, W3 that are outside the stated ranges are also contemplated as embodiments herein. In some embodiments, the second and third widths W2, W3 are the same as each other or substantially the same as each other, such as when the conductive feature 210 has a vertical profile instead of the tapered profile.

In FIG. 2B, each of the conductive features 210 is positioned over one or more interconnect layers. For example, the conductive feature 210 may be formed and positioned on a first conductive layer 220. The first conductive layer 220 can have first width W1. The first width W1 generally exceeds the third width W3 and may exceed the second width W2 or be similar to or slightly less than the second width W2. In some embodiments, the first width W1 is in a range of about 5 nm to about 150 nm. The liner layer 212 may extend to a first depth H1 that is below an upper surface of the first conductive layer 220. The first depth H1 can be referred to as height of the conductive feature 210. The first depth H1 may be in a range of about 1 nm to about 200 nm. In some embodiments, the first depth H1 exceeds one or more of the first, second and third widths W1, W2, W3. In some embodiments, the core layer 214 extends to a second depth that is below the upper surface of the first conductive layer 220, at about the upper surface of the first conductive layer 220 or slightly above the upper surface of the first conductive layer 220. The first conductive layer 220 may be positioned on a first via 232. The first via 232 may be positioned on a second conductive layer 230. Additional vias and conductive layers similar to those just described may underlie the second conductive layer 230, as will be described with reference to FIG. 2C.

FIG. 2C illustrates a diagrammatic side view of the test pattern of FIG. 2A along cross-sectional line B-B, in accordance with some embodiments.

In FIG. 2C, a first conductive feature 210A overlies a first conductive layer 220, a first via 232 and a second conductive layer 230. A second conductive feature 210B immediately adjacent the first conductive feature 210A overlies a first conductive layer 220, a first via 232, a second conductive layer 230, a second via 242 and a third conductive layer 240. A third conductive feature 210C immediately adjacent the second conductive feature 210B overlies a first conductive layer 220, a first via 232, a second conductive layer 230, a second via 242, a third conductive layer 240, a third via 252 and a fourth conductive layer 250.

As depicted in FIG. 2C, the first conductive feature 210A is electrically isolated from the third conductive layer 240 and the fourth conductive layer 250. The second conductive feature 210B is in electrical connection with the third conductive layer 240 and is electrically isolated from the fourth conductive layer 250.

FIG. 2D illustrates a diagrammatic side view of the test pattern of FIG. 2A along the line D-D of FIG. 2C, in accordance with some embodiments.

In FIG. 2D, a fourth conductive feature 210D is immediately adjacent the first conductive feature 210A, and a fifth conductive feature 210E is immediately adjacent the fourth conductive feature 210D. The fourth conductive feature 210D is positioned between the first and fifth conductive features 210A, 210E along the first direction D1. Due to the hexagonal profile and honeycomb arrangement of the conductive features 210A, 210B, 210C, 210D, 210E, as described with reference to FIG. 2A, spacing between the fourth conductive feature 210D and the first and/or fifth conductive feature 210A, 210E exceeds that between the first conductive feature 210A and the second conductive feature 210B shown in FIG. 2C.

As described with reference to FIG. 2C, the first conductive feature 210A depicted in FIG. 2D is electrically isolated from the third conductive layer 240 and the fourth conductive layer 250. The first conductive feature 210A is electrically connected to a second conductive line 230L of the second conductive layer 230 via a first conductive contact 220C of the first conductive layer 220 and a first via 232. The second conductive line 230L can be biased with or can carry a first reference voltage. In some embodiments, the second conductive line 230L can be biased with at least two different reference voltages via one or more switches that can couple or decouple the second conductive line 230L to or from each of at least two voltage sources that supply the at least two different reference voltages, respectively.

The fourth conductive feature 210D is electrically isolated from the fourth conductive layer 250 and is electrically connected to a third conductive line 240L of the third conductive layer 240. The fourth conductive feature 210D is electrically connected to the third conductive line 240L via a first conductive contact 220C, a first via 232, a second conductive contact 230C of the second conductive layer 230 and a second via 242. The third conductive line 240L can be biased with or can carry a second reference voltage. In some embodiments, the third conductive line 240L can be biased with the at least two different reference voltages via one or more switches that can couple or decouple the third conductive line 240L to or from each of the at least two voltage sources that supply the at least two different reference voltages, respectively.

The fifth conductive feature 210E is electrically connected to a fourth conductive line 250L of the fourth conductive layer 250. The fifth conductive feature 210E is electrically connected to the fourth conductive line 250L via a first conductive contact 220C, a first via 232, a second conductive contact 230C, a second via 242, a third conductive contact 240C of the third conductive layer 240 and a third via 252. The fourth conductive line 250L can be biased with or can carry the first reference voltage, the second reference voltage, a third reference voltage or the like. In some embodiments, the fourth conductive line 250L can be biased with the at least two different reference voltages via one or more switches that can couple or decouple the fourth conductive line 250L to or from each of the at least two voltage sources that supply the at least two different reference voltages, respectively.

In FIG. 2D, three conductive features 210A, 210D, 210E are illustrated that are electrically connected to three respective conductive lines 230L, 240L, 250L that are arranged in a staggered manner at three different depths (e.g., at three different metal layers 230, 240, 250). In some embodiments, conductive lines arranged in a staggered manner at fewer or more than three different depths or metal layers than those described with reference to FIG. 2D are included. For example, the test pattern 200 can include conductive lines arranged in a staggered manner at four different depths, five different depths, or more. Three different depths are illustrated and described with reference to FIG. 2D for simplicity of illustration and description and should not be considered an upper limit of the embodiments.

In operation, according to one example, the second reference voltage can exceed the first reference voltage, and the second reference voltage can be supplied to the fourth conductive feature 210D via the third conductive line 240L and the first reference voltage can be supplied to the first conductive feature 210A via the second conductive line 230L. In response to a bridging defect being present on and between the first and fourth conductive features 210A, 210D, electrical current flows through the second and third conductive lines 230L, 240L in response to the voltage difference that is present across the first and fourth conductive features 210A, 210D. In response to no bridging defect being present on and between the first and fourth conductive features 210A, 210D, no or substantially no electrical current flows through the second and third conductive lines 230L, 240L as a result of the first and fourth conductive features 210A, 210D being electrically isolated from each other. Similar operations can be performed to determine presence or absence of a bridging defect between the first and fifth conductive features 210A, 210E and/or between the fourth and fifth conductive features 210D, 210E.

FIG. 2E illustrates a diagrammatic plan view of the test pattern 200, in accordance with some embodiments.

In the test pattern 200 depicted in FIG. 2E, the conductive features 210 have square or rectangular profile instead of the hexagonal profile described with reference to FIG. 2A. The conductive features 210 are arranged in an array including rows of conductive features 210 and columns of conductive features 210. In some embodiments, the row and columns are aligned, as depicted. In some embodiments, one or more of the rows or columns is staggered. For example, conductive features 210 of alternating rows may be staggered relative to each other or conductive features 210 of alternating columns may be staggered relative to each other.

FIG. 2F illustrates a diagrammatic side view of the test pattern of FIG. 2E along cross-sectional line F-F, in accordance with some embodiments. FIG. 2F illustrates dimensions W1, W2, W3, H1, T1, which are the same as or substantially the same as the dimensions W1, W2, W3, H1, T1 described with reference to FIG. 2B.

In FIG. 2F, left, center and right conductive features 210L, 210N, 210R arranged along the second direction D2 are alternately coupled electrically to the second conductive layer 230 and the third conductive layer 240. The center conductive feature 210N is between the left and right conductive features 210L, 210R. In some embodiments, the left conductive feature 210L and the right conductive feature 210R are each electrically isolated from the third conductive layer 240 and the center conductive feature 210N is electrically connected to the third conductive layer 240. Each of the left and right conductive features 210L, 210R is electrically connected to the second conductive layer 230. It should be understood that “left,” “center” and “right” are relative terms and are not intended to limit the embodiments. For example, “left” does not require a feature be “leftmost,” nor does “center” require a feature be in the center of a wafer, die, circuit, scribe line, die perimeter, or otherwise.

FIG. 2G illustrates a diagrammatic side view of the test pattern of FIG. 2E along cross-sectional line G-G of FIG. 2F, in accordance with some embodiments.

In FIG. 2G, a conductive feature 210M is immediately adjacent the left conductive feature 210L. Due to the rectangular or square profile and arrangement of the conductive features 210 described with reference to FIG. 2E, spacing between the left conductive feature 210L and the conductive feature 210M can be the same as or substantially the same as that between the left conductive feature 210L and the center conductive feature 210N shown in FIG. 2F.

As described with reference to FIG. 2F, the left conductive feature 210L depicted in FIG. 2F is electrically isolated from the third conductive layer 240. The left conductive feature 210L is electrically connected to a second conductive line 230L of the second conductive layer 230 via a first conductive contact 220C of the first conductive layer 220 and a first via 232. The second conductive line 230L can be biased with or can carry a first reference voltage. In some embodiments, the second conductive line 230L can be biased with at least two different reference voltages via one or more switches that can couple or decouple the second conductive line 230L to or from each of at least two voltage sources that supply the at least two different reference voltages, respectively.

The conductive feature 210M is electrically connected to a third conductive line 240L of the third conductive layer 240. The conductive feature 210M is electrically connected to the third conductive line 240L via a first conductive contact 220C, a first via 232, a second conductive contact 230C and a second via 242. The third conductive line 240L can be biased with a second reference voltage. In some embodiments, the third conductive line 240L can be biased with the at least two different reference voltages via one or more switches that can couple or decouple the third conductive line 240L to or from each of the at least two voltage sources that supply the at least two different reference voltages, respectively.

In operation, according to one example, the second reference voltage can exceed the first reference voltage, and the second reference voltage can be supplied to the conductive feature 210M via the third conductive line 240L and the first reference voltage can be supplied to the left conductive feature 210L via the second conductive line 230L. In response to a bridging defect being present on and between the left conductive feature 210L and the conductive feature 210M, electrical current flows through the second and third conductive lines 230L, 240L in response to the voltage difference that is present across the left conductive feature 210L and the conductive feature 210M. In response to no bridging defect being present on and between the left conductive feature 210L and the conductive feature 210M, no or substantially no electrical current flows through the second and third conductive lines 230L, 240L as a result of the left conductive feature 210L and the conductive feature 210M being electrically isolated from each other.

FIG. 2H illustrates a diagrammatic side view of a test pattern 200 including a well bridging defect 212B, in accordance with some embodiments.

A process that forms the liner layer 212 can include forming openings 21 that expose respective upper surfaces of the first conductive contacts 220C. The openings 21 can be formed in an insulating layer 216, which may be referred to as a dielectric layer 216. In some embodiments, the insulating layer 216 may be a single layer made of silicon oxide, tetraethyl orthosilicate (TEOS), phosphosilicate glass (PSG), borosilicate glass (BSG), boron-doped phosphosilicate glass (BPSG), fluorosilicate glass (FSG), undoped silicate glass (USG), or the like. The insulating layer 216 may be deposited using any suitable method, such as a chemical vapor deposition (CVD) process, a plasma enhanced CVD (PECVD) process, flowable CVD (FCVD) process, the like, or a combination thereof.

The openings 21 can be formed by one or more suitable etching operations. In some embodiments, the etching operation(s) remove a portion of the first conductive contacts 220C, as depicted in FIG. 2H.

Then, material of the liner layer 212 is deposited on surfaces of the insulating layer 216 and the first conductive contacts 220C exposed by the openings 21, including on an upper surface of the insulating layer 216. Deposition of the material of the liner layer 212 can be or include PVD, CVD, ALD, or the like.

Excess material of the liner layer 212 is then removed from the upper surface of the insulating layer 216. As depicted in FIG. 2H, removal of the liner layer 212 is not complete in some instances, which results in a bridging defect 212B. The bridging defect 212B results in leakage current between conductive features 210 that are formed in a subsequent operation.

In some embodiments, the bridging defect 212B is a result of a cause other than that just described. For example, instead of being due to incomplete removal of the liner layer 212, the bridging defect 212B may be a result of impurities, such as dust or particles, that are present in the processing environment in which the liner layer 212 is formed. The particle may settle on the upper surface of the insulating layer 216 and form a bridge between neighboring portions of the insulating layer 216.

FIG. 2I illustrates a diagrammatic side view of the test pattern 200 including a via or contact bridge defect 260D, in accordance with some embodiments. Following formation of the liner layer 212, the core layer 214 is formed on the liner layer 212 in the openings 21. In some embodiments, the core layer 214 includes a metal, such as copper, aluminum, cobalt, tungsten, ruthenium, combinations thereof and the like. Formation of the core layer 214 can include one or more of electroplating, CVD, ALD, or the like. A CMP may be performed following formation of material of the core layer 214 to remove excess material that is on the upper surface of the insulating layer 216.

Following formation of the core layer 214, vias or contacts 260 may be formed on the conductive features 210, such as directly on the upper surfaces of the liner and core layers 212, 214. A first contact 260A and a second contact 260B are labeled in FIG. 2I. The contacts 260, including the first and second contacts 260A, 260B, may be formed by a process that includes one or more of (i) forming a dielectric layer, (ii) forming openings in the dielectric layer via a patterned mask, (iii) removing the mask, (iv) depositing conductive material in the openings and (v) removing excess material from above the openings. In the process just described, a contact bridge defect 260D can result from, for example, a defect in the patterned mask that results in etching of the dielectric layer between neighboring openings. This type of defect in the patterned mask may be more likely to occur when distance between openings is small. FIG. 2I depicts a situation in which the contact bridge defect 260D is present between the first and second contacts 260A, 260B.

In the test patterns 200 described with reference to FIGS. 2H and 2I, the bridging defect 212B and the contact bridge defect 260D are generally present (when present) between two immediately adjacent conductive features 210. A single bottom conductive line can be included that electrically couples to all conductive features 210 of the test pattern 200 depicted in FIGS. 2H and 2I. Resistance variations in the bottom conductive line can be detected to determine whether a bridging defect is present in the conductive features 210. However, while the single bottom conductive line can be used to determine that the bridging defect is present among the conductive features 210 coupled thereto, precise position of the bridging defect is difficult to determine.

The embodiments described with reference to FIGS. 2A-2G provide pinpoint detection of the bridging defect 212B and/or the contact bridge defect 260D via staggered conductive lines that electrically connect to the individual conductive features 210.

Operation of the test patterns 200 as just described can provide beneficial information about process steps in the semiconductor manufacturing process used to form the conductive features 210 and corresponding conductive features in the die regions 110. For example, conductive features 210 of the test patterns 200 can be separated by varied distances to determine suitability of design rules for layout of active conductive features of the IC die regions 110. The design rule for minimum spacing between adjacent conductive features may specify a first dimension. The conductive features 210 of the test pattern 200 may have spacing therebetween having a second dimension that exceeds or is less than the first dimension associated with the minimum spacing specified by the design rule. Detection of a bridging defect in the test pattern 200 can provide information about whether, for example, spacing tighter than that specified by the design rule can be employed safely throughout the IC die regions 110.

FIG. 3A illustrates a schematic view of an electronic test circuit 300 for detecting a bridge defect, in accordance with some embodiments. The bridge defect can be the bridging defect 212B or the contact bridge defect 260D described with reference to FIGS. 2A-2I, but is not limited thereto. In some embodiments, the electronic test circuit 300 is electrically connected to the test pattern 200 described with reference to FIGS. 2A-2I. Throughout the description, the electronic test circuit 300 may be referred to simply as “the test circuit 300” or “the circuit 300.”

The circuit 300 receives or generates first and second reference voltages VREF1, VREF2 and outputs a first and/or second output signal OUT1, OUT2 associated with electrical current detected by a first and/or second current detection circuit 331, 332 when the first and second reference voltages VREF1, VREF2 are supplied to different conductive features 210 of the test pattern 200. The circuit 300 can include the first current detection circuit 331, the second current detection circuit 332 or both.

The first and second reference voltages VREF1, VREF2 are at or have different voltage levels or values. For example, the first reference voltage VREF1 may have level that exceeds the second reference voltage VREF2. In one example, the first reference voltage VREF1 may have a level of about 1 Volt and the second reference voltage VREF2 may have a level of about 0.5 Volts. Other levels for the first and second reference voltages VREF1, VREF2 are contemplated as embodiments herein. Generally, the first and second reference voltages VREF1, VREF2 are at different levels than each other to establish a potential difference across two voltage output lines that supply the respective first and second reference voltages VREF1, VREF2 to different conductive features 210 of the test pattern 200. Each of the first and second reference voltages VREF1, VREF2 is generated and supplied by a respective reference voltage circuit, which can be an integrated circuit of the die region 110, an external circuit of a test apparatus, or both.

The circuit 300 includes at least two test voltage supply lines 310, each of which is operable to supply one of the first or second reference voltages VREF1, VREF2. First, second, third, fourth, fifth and sixth test voltage supply lines 311, 312, 313, 314, 315, 316 (or “first to sixth test voltage supply lines 311-316”) are illustrated in FIG. 3A. In some embodiments, more or fewer test voltage supply lines 310 than shown in FIG. 3A are included in the circuit 300. For example, FIG. 2A depicts twenty-two conductive features 210, and the circuit 300 may include twenty-two test voltage supply lines 310, each of which is electrically connected to a respective one of the twenty-two conductive features 210. Generally, each of the conductive features 210 is electrically connected to a single test voltage supply line of the at least two test voltage supply lines 310. Including additional test voltage supply lines that are electrically connected to the conductive features 210, for example, as a benefit to improve redundancy, is also contemplated as an embodiment herein.

As described with reference to FIG. 2D, one or more of the first to sixth test voltage supply lines 311-316 may be positioned at a different depth or different metal layer than another or others of the first to sixth test voltage supply lines 311-316. For example, the first test voltage supply line 311 may be positioned at a first depth, the second test voltage supply line 312 may be positioned at a second depth that exceeds the first depth, and the third test voltage supply line 313 may be positioned at a third depth that exceeds the second depth and the first depth. One or more of the first to sixth test voltage supply lines 311-316 may be positioned at the same depth as another or others of the first to sixth test voltage supply lines 311-316. For example, the first test voltage supply line 311 and the fourth test voltage supply line 314 may be positioned at the same depth as each other.

Each of the first to sixth test voltage supply lines 311-316 supplies a respective test voltage signal V1, V2, V3, V4, V5, V6 to the test pattern 200, as depicted in FIG. 3A. The test voltage signals V1, V2, V3, V4, V5, V6 can be alternately the first reference voltage VREF1 or the second reference voltage VREF2 when connected thereto, can be floating when neither of the first and second reference voltages VREF1, VREF2 is supplied thereto, or can be another reference voltage when more than two reference voltages can be supplied to the first to sixth test voltage supply lines 311-316.

In some embodiments, the first and second reference voltages VREF1, VREF2 are supplied to the first to sixth test voltage supply lines 311-316 via respective first switches 361 and second switches 362. Each first switch 361 is electrically connected to a first reference voltage supply line 341 that supplies the first reference voltage VREF1 and is electrically connected to a respective test voltage supply line of the first to sixth test voltage supply lines 311-316. Each second switch 362 is electrically connected to a second reference voltage supply line 342 that supplies the second reference voltage VREF2 and is electrically connected to a respective test voltage supply line of the first to sixth test voltage supply lines 311-316.

The test circuit 300 includes the first current detection circuit 331, the second current detection circuit 332 or both. The first current detection circuit 331 is electrically connected to the first reference voltage supply line 341 and/or optionally to the first reference voltage supply that supplies the first reference voltage VREF1 to the first reference voltage supply line 341. The first current detection circuit 331 is operable to determine whether electrical current flows through the first reference voltage supply line 341, such as when a bridging defect is present between two of the conductive features 210. In some embodiments, the first current detection circuit 331 is or includes one or more of a Hall effect sensor, a current mirror circuit, a transimpedance amplifier (TIA), a MOSFET-based current sensor, a magnetic sensor (e.g., a giant magnetoresistance or “GMR” sensor, an anisotropic magnetoresistance or “AMR” sensor, or the like), a current transformer, a Rogowski coil or the like.

The second current detection circuit 332 is electrically connected to the second reference voltage supply line 342 and/or optionally to the second reference voltage supply that supplies the second reference voltage VREF2 to the second reference voltage supply line 342. The second current detection circuit 332 is operable to determine whether electrical current flows through the second reference voltage supply line 342, such as when a bridging defect is present between two of the conductive features 210. In some embodiments, the second current detection circuit 332 is or includes one or more of a Hall effect sensor, a current mirror circuit, a transimpedance amplifier (TIA), a MOSFET-based current sensor, a magnetic sensor (e.g., a giant magnetoresistance or “GMR” sensor, an anisotropic magnetoresistance or “AMR” sensor, or the like), a current transformer, a Rogowski coil or the like.

In embodiments in which more than two reference voltages are supplied to the test pattern 200 via the circuit 300, additional current detection circuits similar to the first and second current detection circuits 331, 332 may be included in the circuit 300.

FIG. 3B illustrates a schematic view of the electronic test circuit of FIG. 3A in a first detecting state, in accordance with some embodiments.

In the first detecting state, a first switch 361A of the first switches 361 and a second switch 362A of the second switches 362 are closed to supply the first reference voltage VREF1 to the first test voltage supply line 311 and the second reference voltage VREF2 to the second test voltage supply line 312, respectively. Other switches of the first and second switches 361, 362 are opened to keep the third, fourth, fifth and sixth test voltage supply lines 313, 314, 315, 316 in an electrically floating state.

In the first detecting state, when a bridging defect is present across conductive features electrically connected to the first and second test voltage supply lines 311, 312, the first and/or second current detection circuit 331, 332 will output first and/or second output signals OUT1, OUT2 having level that exceeds a threshold level. For example, the first and/or second output signal OUT1, OUT2 may be a voltage that exceeds a threshold voltage when the bridging defect is present.

FIG. 3C illustrates a schematic view of the electronic test circuit 300 for detecting a bridge defect, in accordance with some embodiments.

In FIG. 3C, in some embodiments, the circuit 300 can include more than two reference voltages, such as the first and second reference voltages VREF1, VREF2. In some embodiments, the circuit 300 includes the first and second reference voltages VREF1, VREF2 and third and fourth reference voltages VREF3, VREF4. The third and fourth reference voltages VREF3, VREF4 may be supplied by third and fourth voltage supplies that are different than the first and second voltage supplies. In some embodiments, the third and fourth reference voltages VREF3, VREF4 can have the same voltage levels as the respective first and second reference voltages VREF1, VREF2 but are supplied independently by different voltage supplies than those that supply the first and second reference voltages VREF1, VREF2.

The circuit 300 includes third switches 363 and fourth switches 364 that respectively electrically connect to the third voltage supply and the fourth voltage supply and to the fourth, fifth and sixth test voltage supply lines 314, 315, 316.

Including the third and fourth references voltages VREF3, VREF4 and the third and fourth switches 363, 364 can provide parallel testing of pairs of conductive features 210, which can increase testing speed and reduce testing time. In some embodiments, additional reference voltages and additional switches can be included to provide additional parallel testing paths than those described with reference to FIG. 3C.

FIG. 3D illustrates a schematic view of an electronic test circuit 300 that is electronically connected to a test pattern 200, in accordance with some embodiments.

In FIG. 3D, conductive lines 230L, 240L, 250L, which can be the same as the test voltage supply lines 310, are positioned to connect the test circuit 300 to the conductive features 210 of the test pattern 200. The conductive lines 230L are depicted as solid lines, the conductive lines 240L are depicted as dot-dashed lines and the conductive lines 250L are depicted as double-dot-dashed lines. In some embodiments, the conductive lines 230L are connected to first conductive features 210 proximal the circuit 300, the conductive lines 250L are connected to second conductive features 210 distal the circuit 300 and the conductive lines 240L are connected to third conductive features 210 between the first and second conductive features 210. Although illustrated as being offset from each other along the second direction D2, the conductive lines 240L and the conductive lines 250L may extend directly beneath the conductive lines 230L, as depicted in FIGS. 2C and 2D. Namely, the conductive lines 240L may overlap the conductive lines 250L, and the conductive lines 230L may overlap the conductive lines 240L. It should be noted that the arrangement of the conductive lines 230L, 240L, 250L may be slightly different in FIG. 3D relative to that illustrated in FIG. 2C. For example, in FIG. 3D, all of the conductive features 210 in the right two columns (relative to the page) are connected to the conductive lines 230L, whereas in FIG. 2C, some of the conductive features 210 in the same column (e.g., the second-to-right column of FIG. 2A) are connected to the conductive lines 240L or the conductive lines 250L.

FIG. 3E illustrates a schematic view of at least two electronic test circuits 300 that are electronically connected to a test pattern 200, in accordance with some embodiments.

In some embodiments, in addition to or instead of the test circuit 300 positioned on the right or first side of the test pattern 200 (relative to the page), a second test circuit that is similar in most respects to the test circuit 300 may be positioned on the opposite or second side of the test pattern 200 (e.g., the left side relative to the page). Alternating columns of the conductive features 210 can be respectively electrically connected to the test circuit 300 on the first side or the test circuit 300 on the second side.

In operation, the reference voltages VREF1, VREF2, VREF3, VREF4 can be supplied to pairs of conductive features 210 in different columns via both of the test circuits 300 and can be supplied to pairs of conductive features 210 in the same column by the respective test circuit 300 connected thereto.

Although not separately illustrated, a third and fourth test circuit that are the same in most respects to the test circuit 300 described with reference to FIGS. 3A-3C can be positioned on third and fourth sides (e.g., top and bottom sides relative to the page) of the test pattern 200.

Including at least two test circuits 300 arranged as just described can be beneficial to increase available spacing between the test voltage supply lines 310, which can simplify formation of the test voltage supply lines 310.

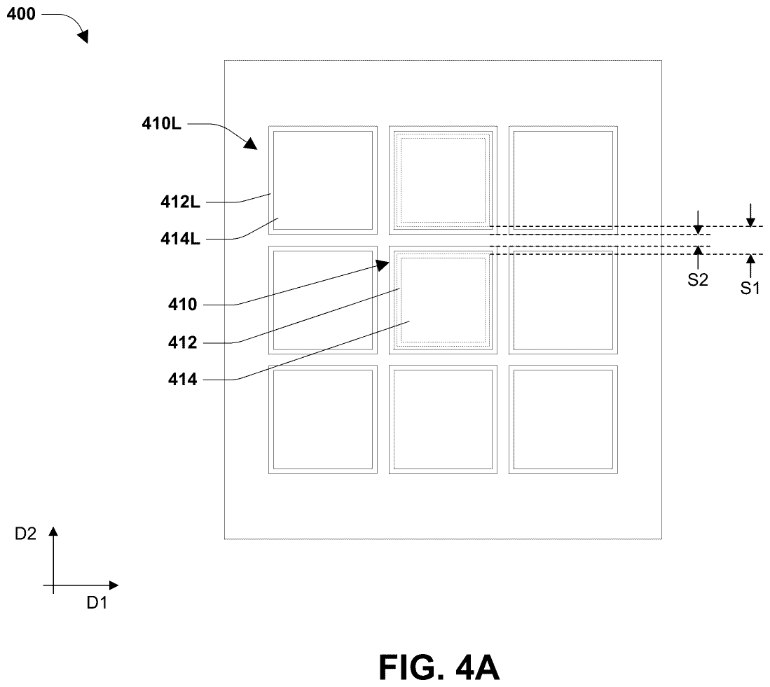

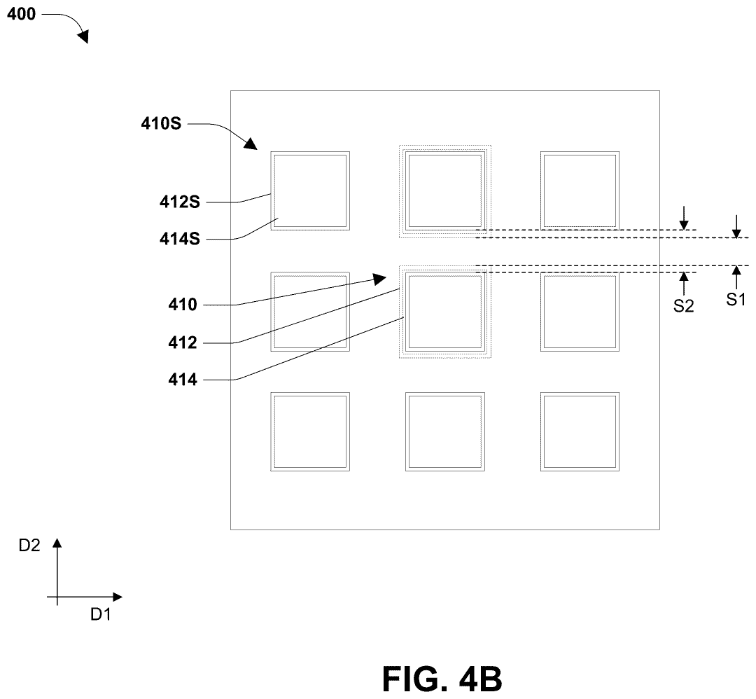

FIG. 4A illustrates a diagrammatic plan view of a test pattern 400, in accordance with some embodiments.

The test pattern 400 illustrated in FIG. 4A may be similar in most respects to the test pattern 200 illustrated in FIG. 2E. As discussed with reference to FIG. 1B, the test pattern 400 (or the test pattern 200) may be beneficial for determining whether a design rule, such as minimum spacing between features, can be tightened or loosened. Namely, the test patterns 200, 400 may be beneficial for determining effects of tightening or loosening a design rule. For example, successful tightening of a minimum spacing design rule can result in benefits, such as increased circuit feature density and/or reduced chip area.

In the test pattern 400 of FIG. 4A, large conductive features 410L are arranged instead of conductive features 410 that follow a minimum spacing design rule. Position and size of two conductive features 410 are depicted in phantom by dashed lines in FIG. 4A, including liner layer regions 412 and core layer regions 414. A first spacing S1 that is associated with the design rule is present between neighboring conductive features 410, as depicted.

The large conductive features 410L include liner layers 412L and core layers 414L. Second spacing S2 between the large conductive features 410L is less than the first spacing S1. The first and second spacings S1, S2 are depicted as being along the second direction D2, but may also be along the first direction D1. For example, the reduced spacing S2 may be present along both horizontal and vertical axes between rows and columns of the conductive features 410L.

FIG. 4B illustrates a diagrammatic plan view of a test pattern 400, in accordance with some embodiments.

The test pattern 400 of FIG. 4B is similar in most respects to the test pattern 400 of FIG. 4A. In FIG. 4B, the test pattern 400 includes small conductive features 410S, which are separated by a second spacing S2 that exceeds the first spacing S1 associated with the design rule. The small conductive features 410S include liner layers 412S and core layers 414S.

In FIGS. 4A and 4B, the first spacing S1 and the second spacing S2 can differ by an amount that is less than about 5%. For example, active conductive features of the IC die region 110 can be arranged according to the first spacing S1 that is associated with the minimum spacing design rule, and conductive features 410L of the test pattern 400 can be arranged according to the second spacing S2 that is in a range of about 95% to 99.9% of the first spacing S1. In another example, the conductive features 410S of the test pattern 400 can be arranged according to the second spacing S2 that is in a range of about 100.1% to about 105% of the first spacing S1.

The conductive features 410S, 410L, 410 depicted in FIGS. 4A and 4B are rectangular (e.g., square) in profile. In some embodiments, the conductive features 410S, 410L, 410 have hexagonal or other polygonal profile instead of the rectangular profile.

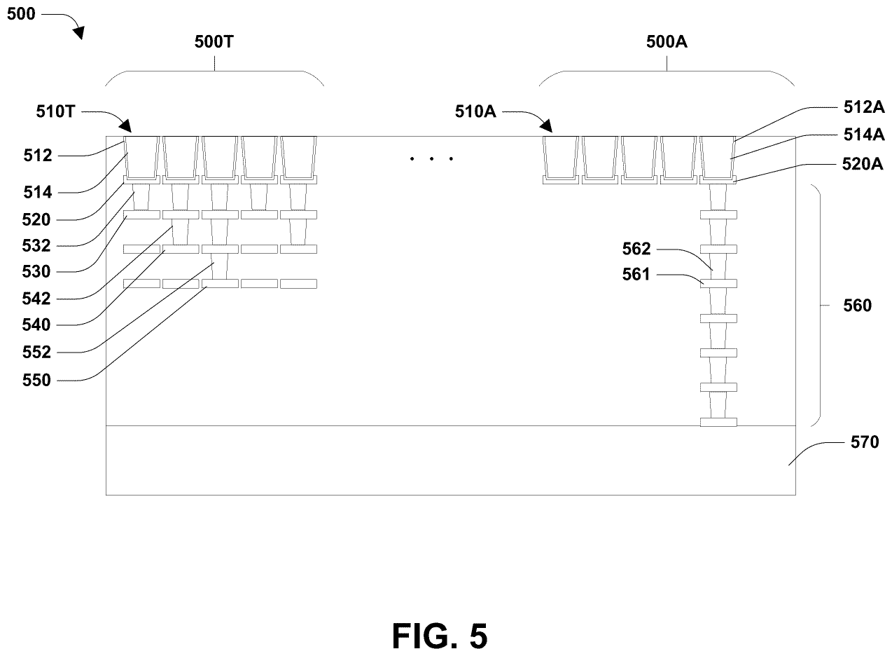

FIG. 5 illustrates a schematic view of a portion 500 of a wafer including a test pattern 500T, in accordance with some embodiments.

In FIG. 5, a wafer includes a portion 500 that has an active circuit region 500A and a test pattern 500T that is offset from the active circuit region 500A. As described with reference to FIGS. 1A and 1B, the active circuit region 500A can be positioned in an IC die region (e.g., the IC die region 110) and the test pattern 500T can be positioned in the IC die region, in a scribe line or in a chip perimeter between the IC die region and the scribe line.

The active circuit region 500A includes conductive features 510A that can be top metal features, but can also be lower metal features in some embodiments. The conductive features 510A are similar in most respects to the conductive features 210 described with reference to FIGS. 2A-2I. In some embodiments, the conductive features 510A include liner layers 512A and core layers 514A and are positioned on first conductive layers 520A. One or more of the conductive features 510A can be electrically connected to a device layer 570 via an interconnect structure 560, which can include one or more stacks of alternating contacts 561 and vias 562.

The test pattern 500T is similar in most respects to the test patterns 200 described with reference to FIGS. 2A-2I and/or the test patterns 400 described with reference to FIGS. 4A and 4B. The test pattern 500T includes conductive features 510T that are similar in most respects to the conductive features 210, 410S, 410L described with reference to FIGS. 2A-2I, 4A and 4B. The conductive features 510T include liner layers 512 and core layers 514 that are similar in most respects to the liner and core layers 212, 214, 412S, 412L, 414S, 414L described with reference to FIGS. 2A-2I, 4A and 4B.

The test pattern 500T includes first conductive layers or contacts 520, first vias 532, second conductive layers or contacts 530, second vias 542, third conductive layers or contacts 540, third vias 552 and fourth conductive layers or contacts 550, which may be similar in most respects to the first conductive layers or contacts 220, 220C, first vias 232, second conductive layers or contacts 230, 230C, second vias 242, third conductive layers or contacts 240, 240C, third vias 252 and fourth conductive layers or contacts 250, 250C described with reference to FIGS. 2A-2I.

Each of the first conductive layers or contacts 520, first vias 532, second conductive layers or contacts 530, second vias 542, third conductive layers or contacts 540, third vias 552 and fourth conductive layers or contacts 550 may be formed and positioned in the same metal layer as corresponding layers or vias of the interconnect structure 560 in the active circuit region 500A.

As described with reference to FIGS. 4A and 4B, dimensions of the conductive features 510T of the test pattern 500T may be the same as dimensions of the conductive features 510A of the active circuit region 500A. In some embodiments, the dimensions of the conductive features 510T are different than (e.g., greater than or less than) the dimensions of the conductive features 510A of the active circuit region 500A. The difference in the dimensions can be less than about 5%, in some embodiments. The difference in the dimensions can exceed 5% in some embodiments, such as being between about 5% and about 10% or in another suitable range different than those just described. In some embodiments, first spacing between neighboring conductive features 510T of the test pattern 500T can be equal to second spacing between neighboring conductive features 510A of the active circuit region 500A. In some embodiments, a ratio of the first spacing over the second spacing can be in a range of about 0.95 to about 1.05, about 0.9 to about 1.1, or another suitable range.

Although the embodiments described with reference to FIGS. 2A-5 are described in the context of conductive features 210, 410, 410L, 410S, 510A, 510T that are positioned in a top metal, it should be understood that the test patterns 200, 400, 500T may be formed at any interconnect layer of the IC die region 110. For example, any of a first metal layer M1 immediately above a gate, source and drain contact layer (or “MD”), a second metal layer M2 immediately above the first metal layer M1, a third metal layer M3 immediately above the second metal layer M2 and so on up to the top metal layer can include the test pattern 200, 400, 500T. In some embodiments, a first test pattern at a first one of the metal layers may differ from a second test pattern at a second one of the metal layers. The difference(s) can include size, arrangement, spacing, profile shape, number and the like of the conductive features of the first and second test patterns.

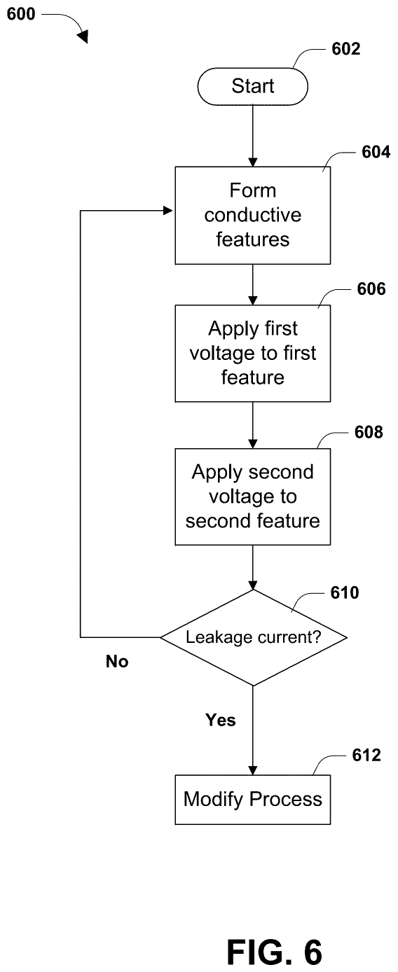

A method 600 is illustrated in FIG. 6 in accordance with some embodiments. The method begins at 602. At 604, the method 600 includes forming conductive features (e.g., the conductive features 210). The forming conductive features can be based on a first manufacturing process. At 606, the method 600 includes applying a first voltage to a first conductive feature of the conductive features. At 608, the method 600 includes applying a different second voltage to a second conductive feature of the conductive features. At 610, the method 600 includes determining whether a leakage current is present during the first and second voltages being applied to the first and second conductive features. At 612, in response to the leakage current being present, a second manufacturing process can be generated by modifying the first manufacturing process. For example, a layout of the conductive features 210 is modified to increase spacing between the conductive features and active conductive features of an IC die (e.g., the IC die region 110). In another example, a process that forms a patterned mask layer used to form openings in which the conductive features are deposited is modified. One or more inspection operations may be performed, such as to determine whether a photomask used to expose the patterned mask layer has a particle bridge thereon or another defect. The photomask may then be cleaned, repaired or replaced.

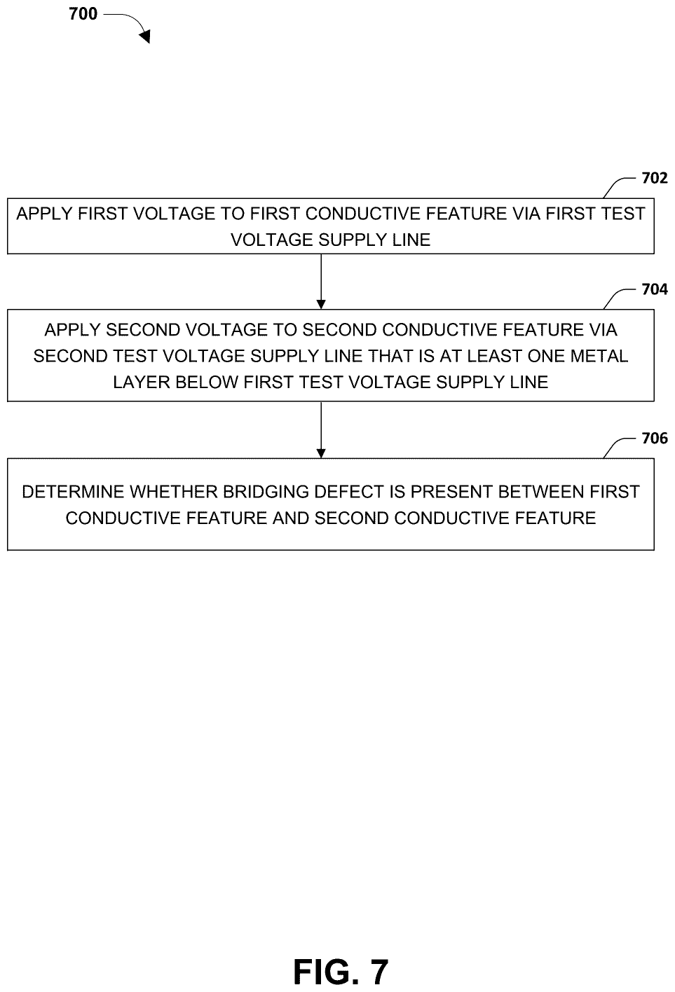

A method 700 is illustrated in FIG. 7 in accordance with some embodiments. At 702, the method 700 includes applying a first voltage to a first conductive feature via a first test voltage supply line. At 704, the method 700 includes applying a second voltage different than the first voltage to a second conductive feature via a second test voltage supply line that is at least one metal layer below the first test voltage supply line. At 706, the method 700 includes determining whether a bridging defect is present between the first conductive feature and the second conductive feature based on an electrical current that flows in at least one of the first test voltage supply line or the second test voltage supply line when the first and second voltages are applied.

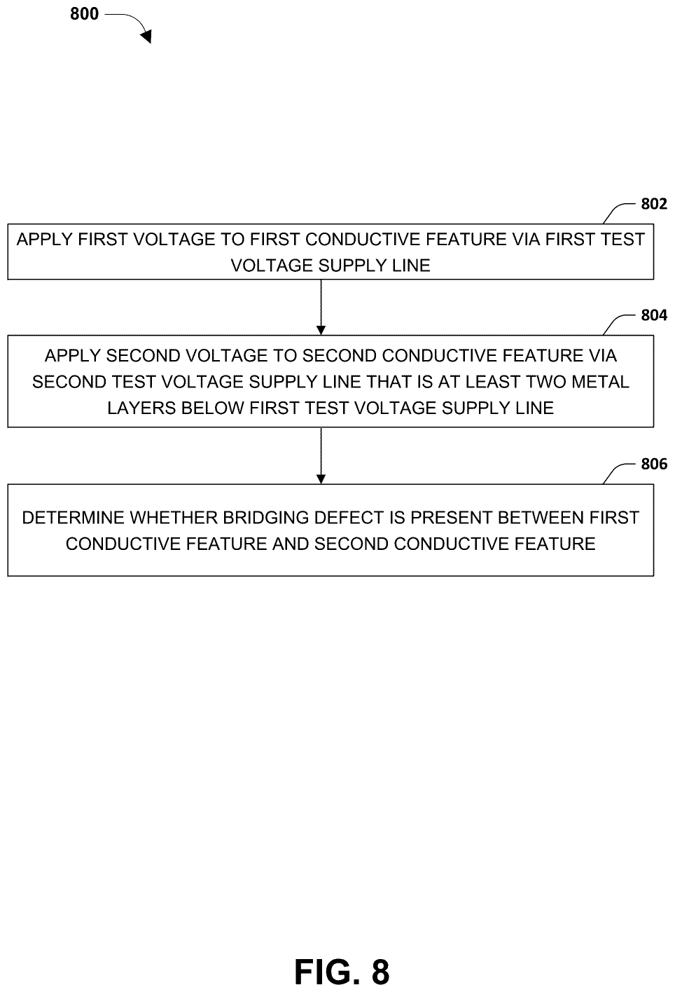

A method 800 is illustrated in FIG. 8 in accordance with some embodiments. At 802, the method 800 includes applying a first voltage to a first conductive feature via a first test voltage supply line. At 804, the method 800 includes applying a second voltage different than the first voltage to a second conductive feature via a second test voltage supply line that is at least two metal layers below the first test voltage supply line. At 806, the method 800 includes determining whether a bridging defect is present between the first conductive feature and the second conductive feature based on an electrical current that flows in at least one of the first test voltage supply line or the second test voltage supply line when the first and second voltages are applied.

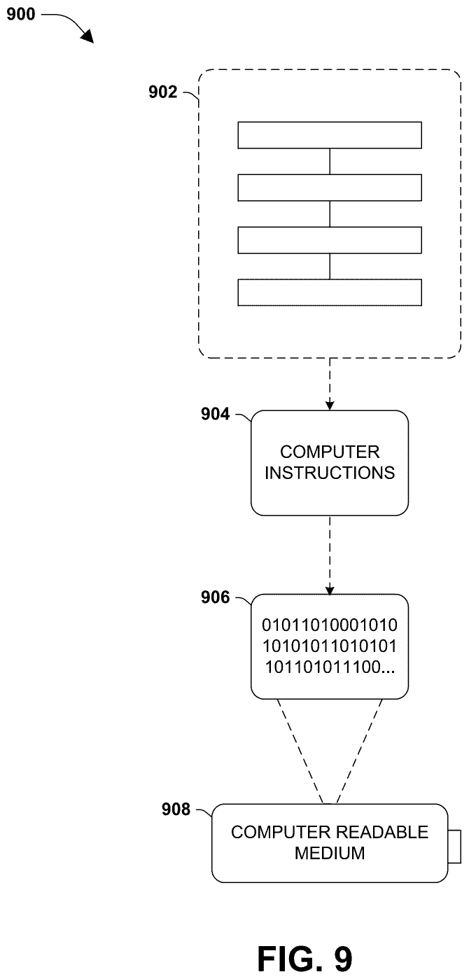

One or more embodiments involve a computer-readable medium comprising processor-executable instructions configured to implement one or more of the techniques presented herein. An exemplary computer-readable medium is illustrated in FIG. 9, wherein the embodiment 900 comprises a computer-readable medium 908 (e.g., a CD-R, DVD-R, flash drive, a platter of a hard disk drive, etc.), on which is encoded computer-readable data 906. This computer-readable data 906 in turn comprises a set of processor-executable computer instructions 904 configured to implement one or more of the principles set forth herein when executed by a processor. In some embodiments 900, the processor-executable computer instructions 904 are configured to implement a method 902, such as at least some of the aforementioned method(s) when executed by a processor. In some embodiments, the processor-executable computer instructions 904 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a device is provided. The device comprises: an active circuit region including a first active conductive feature; and a test pattern offset from the first active conductive feature. The test pattern includes: a first conductive feature in a first metal layer; a second conductive feature in the first metal layer; a first test voltage supply line in a second metal layer below the first metal layer and electrically connected to the first conductive feature; and a second test voltage supply line in a third metal layer below the second metal layer and electrically connected to the second conductive feature.

In some embodiments, a method is provided. The method includes: applying a first voltage to a first conductive feature of a test pattern via a first test voltage supply line; applying a second voltage different than the first voltage to a second conductive feature of the test pattern via a second test voltage supply line, the second test voltage supply line being positioned in a metal layer below that of the first test voltage supply line; and during the applying a first voltage and the applying a second voltage, determining whether a bridging defect is present between the first conductive feature and the second conductive feature based on electrical current that flows in at least one of the first test voltage supply line or the second test voltage supply line.

In some embodiments, a method is provided. The method includes: forming a first conductive feature and a second conductive feature in a test region of a wafer, the forming being associated with a first manufacturing process; during the forming a first conductive feature and a second conductive feature, forming a plurality of active conductive features in an active circuit region of an integrated circuit die region of the wafer; applying a first voltage to the first conductive feature via a first test voltage supply line; during the applying a first voltage, applying a second voltage to the second conductive feature via a second test voltage supply line that is at least one metal layer below the first test voltage supply line; determining whether a leakage current flows through at least one of the first test voltage supply line or the second test voltage supply line; and in response to determining that the leakage current flows, generating a second manufacturing process by modifying the first manufacturing process.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A device, comprising:
an active circuit region including a first active conductive feature; and
a test pattern offset from the first active conductive feature, the test pattern including:
a first conductive feature in a first metal layer;
a second conductive feature in the first metal layer;
a first test voltage supply line in a second metal layer below the first metal layer and electrically connected to the first conductive feature; and
a second test voltage supply line in a third metal layer below the second metal layer and electrically connected to the second conductive feature.

2. The device of claim 1, comprising:
a third conductive feature in the first metal layer; and
a third test voltage supply line in a fourth metal layer below the third metal layer and electrically connected to the third conductive feature.

3. The device of claim 1, wherein the active circuit region comprises a second active conductive feature, the first and second active conductive features being positioned in the first metal layer.

4. The device of claim 3, wherein a ratio of first spacing between the first conductive feature and the second conductive feature over second spacing between the first active conductive feature and the second active conductive feature is in a range of about 0.95 to about 1.05.

5. The device of claim 1, wherein a ratio of a first size of the first conductive feature over a second size of the first active conductive feature is in a range of about 0.95 to about 1.05.

6. The device of claim 1, wherein the first active conductive feature has a same profile shape as that of the first conductive feature.

7. The device of claim 1, wherein the test pattern is positioned in the active circuit region.

8. The device of claim 1, further comprising a chip perimeter that laterally surrounds the active circuit region, wherein the test pattern is positioned in the chip perimeter.

9. A method comprising:
applying a first voltage to a first conductive feature of a test pattern via a first test voltage supply line;
applying a second voltage different than the first voltage to a second conductive feature of the test pattern via a second test voltage supply line, the second test voltage supply line being positioned in a metal layer below that of the first test voltage supply line; and
during the applying a first voltage and the applying a second voltage, determining whether a bridging defect is present between the first conductive feature and the second conductive feature based on electrical current that flows in at least one of the first test voltage supply line or the second test voltage supply line.

10. The method of claim 9, wherein:
the applying a first voltage includes applying the first voltage to the first conductive feature that is positioned in a scribe line of a wafer; and
the applying a second voltage includes applying the second voltage to the second conductive feature that is positioned in the scribe line.

11. The method of claim 9, wherein:
the determining whether a bridging defect is present includes determining whether the bridging defect is present between a first liner layer of the first conductive feature and a second liner layer of the second conductive feature.

12. The method of claim 9, wherein:
the determining whether a bridging defect is present includes determining whether the bridging defect is present between a first via on the first conductive feature and a second via on the second conductive feature.

13. The method of claim 9, wherein the applying a second voltage includes applying the second voltage to the second test voltage supply line that is positioned in the metal layer that is at least two metal layers below the first test voltage supply line.

14. The method of claim 9, wherein the applying a first voltage to a first conductive feature of a test pattern includes applying the first voltage to the first conductive feature of the test pattern, the test pattern having substantially the same arrangement of conductive features as that of a plurality of active conductive features of an active circuit region offset from the test pattern.

15. A method, comprising:
forming a first conductive feature and a second conductive feature in a test region of a wafer, the forming being associated with a first manufacturing process;
during the forming a first conductive feature and a second conductive feature, forming a plurality of active conductive features in an active circuit region of an integrated circuit die region of the wafer;
applying a first voltage to the first conductive feature via a first test voltage supply line;
during the applying a first voltage, applying a second voltage to the second conductive feature via a second test voltage supply line that is at least one metal layer below the first test voltage supply line;
determining whether a leakage current flows through at least one of the first test voltage supply line or the second test voltage supply line; and
in response to determining that the leakage current flows, generating a second manufacturing process by modifying the first manufacturing process.

16. The method of claim 15, wherein the forming a first conductive feature and a second conductive feature includes forming the first conductive feature and the second conductive feature having spacing therebetween that is associated with a design rule.

17. The method of claim 15, wherein the forming a first conductive feature and a second conductive feature includes forming the first conductive feature and the second conductive feature having first spacing therebetween that is tighter than a second spacing associated with a design rule.

18. The method of claim 15, further comprising:
during the forming a first conductive feature and a second conductive feature, forming a third conductive feature and a fourth conductive feature in the test region;
during the applying a first voltage and the applying a second voltage:
applying a third voltage to the third conductive feature via a third test voltage supply line;
applying a fourth voltage to the fourth conductive feature via a fourth test voltage supply line; and
determining whether a second leakage current flows through at least one of the third test voltage supply line or the fourth test voltage supply line.

19. The method of claim 18, wherein the applying a third voltage includes applying the third voltage via the third test voltage supply line that is at least one metal layer below the second test voltage supply line.

20. The method of claim 19, wherein the applying a fourth voltage includes applying the fourth voltage via the fourth test voltage supply line that is in a same metal layer as the first test voltage supply line.
